(19) United States
(12) Patent Application Publication
(10) Pub. No.: US 2009/0315024 A1
(43) Pub. Date: Dec. 24, 2009

(54) ORGANIC LUMINESCENCE DEVICE

(75) Inventors: Won-Jun SONG, Suwon-si (KR); Yeun-Joo Sung, Suwon-si (KR); Sun-Hee Lee, Suwon-si (KR); Mu-Hyun Kim, Suwon-si (KR)

Correspondence Address: STEIN MCEWEN, LLP, 1400 EYE STREET, NW, SUITE 300, WASHINGTON, DC, 20005, US

(73) Assignee: Samsung Mobile Display Co., Ltd., Suwon-si (KR)

(21) Appl. No.: 12/388,872

(22) Filed: Feb. 19, 2009

(30) Foreign Application Priority Data
Jun. 18, 2008 (KR) 2008-57483

(51) Int. Cl. H01L 51/00; H01L 29/12

(52) U.S. Cl. 257/40; 257/43; 257/E29.068; 257/E51.001

(57) ABSTRACT

An organic luminescence device including an electron transport layer, which comprises an electron transporting material and a metal oxide represented by Formula 1: AₐO_{b}. In Formula 1: A is Li, Mo, Ba, B, or Cs; a is a number in the range of 1 to 3; and b is a number in the range of 1 to 3. The electron transporting material reduces an electron injection barrier and the resistance at the interface between an EML and an ETL, resulting in an increase in the lifespan of the organic luminescence device. The numbers of holes and electrons injected to the EML are balanced, and driving characteristics of the organic luminescence device are improved.

### CROSS-REFERENCE TO RELATED APPLICATION

This application claims the benefit of Korean Patent Application No. 2008-57483, filed on Jun. 18, 2008, in the Korean Intellectual Property Office, the disclosure of which is incorporated herein, by reference.

### BACKGROUND OF THE INVENTION

1. Field of the Invention

Aspects of the present invention relate to an organic luminescence device.

2. Description of the Related Art

Organic luminescence devices are self-emission display devices that have wide viewing angles, high contrast ratios, and quick response speeds. Due to these advantages, organic luminescence devices are receiving much attention.

An organic luminescence device includes a hole injection layer, a hole transport layer, an emission layer, an electron transport layer, and a cathode, which are stacked on an anode, in this order. The anode is formed by depositing a transparent conductive material, such as ITO, on a glass substrate.

When a direct current voltage is applied between the anode and cathode, holes are injected from the anode and flow to the emission layer, through the hole injection layer and the hole transport layer. Electrons are injected from the cathode and flow to the emission layer, through the electron transport layer. In the emission layer, the holes are recombined with the electrons to generate light.

However, when an electron transport layer is formed using a conventional electron transporting material, an increase in voltage, with respect to a required luminance, cannot be avoided when the electrons are injected, due to the resistance of the electron transporting material. Therefore, there is a need to develop a novel electron transporting material.

### SUMMARY OF THE INVENTION

Aspects of the present invention provide an organic luminescence device having excellent lifetime characteristics, in which an electron injection barrier is low, and an interface between an emission layer and an electron transport layer has a low resistance.

According to an aspect of the present invention, there is provided an organic luminescence device including an electron transport layer, which contains an electron transporting material and a metal oxide represented by Formula 1:

AₐO_{b} [Formula 1]

wherein A is Li, Mo, Ba, B, or Cs, a is a number in the range of 1 to 3, and b is a number in the range of 1 to 3.

The organic luminescence device may further include a first electrode, a hole injection layer, an emission layer, and a second electrode.

According to another aspect of the present invention, there is provided an organic luminescence device including: a first electron transport layer comprising a first electron transporting material; and a second electron transport layer comprising a second electron transporting material and a metal oxide represented by Formula 1 illustrated below:

AₐO_{b} [Formula 1]

wherein A is Li, Mo, Ba, B, or Cs, a is a number in the range of 1 to 3, and b is a number in the range of 1 to 3.

The organic luminescence device may include, a first electrode, a hole transport layer, an emission layer, and a second electrode.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the exemplary embodiments, taken in conjunction with the accompanying drawings, of which:

FIG. 1 illustrates a stack structure of an organic luminescence device, according to an exemplary embodiment of the present invention;

FIG. 2 illustrates a stack structure of an organic luminescence device, according to another exemplary embodiment of the present invention;

FIG. 3 shows a graph of power efficiency with respect to luminance, of an organic luminescence device, according to an exemplary embodiment of the present invention;

FIG. 4 shows a graph of current density with respect to voltage, of an organic luminescence device, according to an exemplary embodiment of the present invention;

FIG. 5 shows a graph of current efficiency with respect to luminance, of an organic luminescence device, according to an exemplary embodiment of the present invention;

FIG. 6 shows a graph of current density with respect to voltage of an organic luminescence device, according to an exemplary embodiment of the present invention; and

FIG. 7 shows a graph of luminance with respect to voltage, of an organic luminescence device, according to an exemplary embodiment of the present invention.

### DETAILED DESCRIPTION OF THE EXEMPLARY EMBODIMENTS

Reference will now be made in detail to aspects of the exemplary embodiments of the present invention, examples of which are illustrated in the accompanying drawings, wherein like reference numerals refer to the like elements throughout. The exemplary embodiments are described below, in order to explain the aspects of the present invention, by referring to the figures.

As referred to herein, when a first element is said to be disposed or formed “on”, or “adjacent to”, a second element, the first element can directly contact the second element, or can be separated from the second element by one or more other elements located therebetween. In contrast, when an element is referred to as being disposed or formed “directly on” another element, there are no intervening elements present. As used herein, the term “and/or” includes any and all combinations of one or more of the associated listed items

To produce an organic luminescence device having a high efficiency, the charge balance in an emission layer (EML) is considered to be a very important factor. When most carriers are holes (+), a charge flow density of electrons (−) needs to be controlled. To this end, an organic luminescence device, according to aspects of the present invention, includes an electron transport layer (ETL) including a metal oxide represented by the following Formula 1, and an electron transporting material.

AₐO_{b} [Formula 1]

In Formula 1, A is lithium (Li), molybdeum (Mo), barium (Ba), boron (B), or cesium (Cs), a is a number in the range of 1 to 3, and be is a number in the range of 1 to 3. The metal oxide represented by Formula 1 may be lithium oxide (Li₂O), molybdeum oxide (Mo₁O₃), barium oxide (BaO), or boron oxide (B₂O₃).

The organic luminescence device does not include an electron injection layer (EIL), but has excellent electron injection properties. The organic luminescence device may further include, in addition to the ETL described above, another ETL including an electron transporting material having an electron mobility of at least 10⁻⁸ cm/V, in an electric field of from 800 to 1000 (V/cm)^{1/2}.

Specifically, the organic luminescence device includes: a first ETL including a first electron transporting material; and a second ETL including a second electron transporting material and a metal oxide represented by Formula 1. When a double-layered ETL as described above is used, electrons are more easily injected, than when a single-layer ETL is used. Such easy injection of electrons leads to a decrease in a driving voltage, and a significant drop in power consumption.

The first electron transporting material may have an electron mobility of at least 10⁻⁸ cm/V, or more specifically, from 10⁻⁴ to 10⁻³ cm/vs, in an electric field of 800-1000 (V/cm)^{1/2}. For example, the first electron transporting material may be bis(8-oxyquinolino)zinc II (Znq2), or BeBq2 represented by Formula 2:

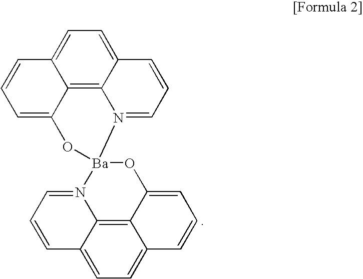

Like the first electron transporting material, the second electron transporting material generally has an electron mobility of at least 10⁻⁸ cm/V. The second electron transporting material may be identical to, or different from, the first electron transporting material. When the first electron transporting material is identical to the second electron material, the efficiency of the organic luminescence device is higher than when the first electron transporting material is different from the second electron material. The ratio of the thickness of the first ETL to the thickness of the second ETL may range from 1:1 to 2:1.

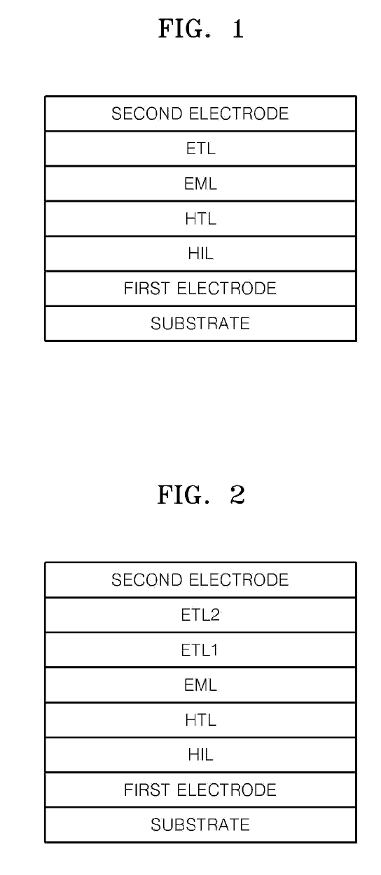

FIG. 1 illustrates a stack structure of an organic luminescence device, according to an exemplary embodiment of the present invention, and FIG. 2 illustrates a stack structure of an organic luminescence device, according to another exemplary embodiment of the present invention. Referring to FIG. 1, the organic luminescence device includes a first electrode, a hole injection layer (HIL), and a hole transport layer (HTL), which are sequentially disposed on a substrate, in this order. In some cases, the HIL may not be included.

In addition, an EML and an ETL, including an electron transporting material and the metal oxide represented by Formula 1, are disposed on the HTL, and a second electrode is disposed on the ETL. Specifically, the electron transporting material may be BeBq2, and the metal oxide represented by Formula 1 may be Li₂O.

Referring to FIG. 2, the organic luminescence device, according to the other exemplary embodiment of the present invention, includes a first electrode, an HIL, and an HTL, which are sequentially formed on a substrate, in this order. In some cases, the HIL may not be included. In addition, an EML, an ETL1, and an ETL2 are disposed on the HTL, and a second electrode is disposed on the ETL2. The ETL1 includes a first electron transporting material, and the ETL2 includes a second electron transporting material and the metal oxide represented by Formula 1.

In the organic luminescence device illustrated in FIG. 2, the ETL1 controls a charge flow speed, and the ETL2 lowers an electron injection barrier. The first electron transporting material of ETL1 may be BeBq2 or Znq2. The ETL2 includes the second electron transporting material and the metal oxide represented by Formula 1. The metal oxide represented by Formula 1 includes Li₂O, Ba₂O, or CsO, and the second electron transporting material includes BeBq2 or Znq2.

Referring to FIGS. 1 and 2, the organic luminescence devices do not include an EIL. However, according to other embodiments, an EIL can be included. Hereinafter, a method of manufacturing an organic luminescence device, according to an embodiment of the present invention will be described in detail.

First, a material for forming a first electrode is coated on a substrate, to form a first electrode. The first electrode may be an anode. The substrate may be any substrate that is used to form a conventional organic luminescence device. For example, the substrate may be a transparent and waterproof, glass or plastic planar substrate. The material for forming the first electrode may be a transparent and conductive material, such as indium tin oxide (ITO), indium zinc oxide (IZO), tin oxide (SnO₂), or zinc oxide (ZnO).

The HIL can be formed by vacuum depositing, or spin coating, a hole injecting material. The hole injecting material may be a phthalocyanine compound, such as a copper phthalocyanine disclosed in U.S. Pat. No. 4,356,429, or a star-burst amine derivative, such as TCTA, m-MTDATA, or m-MTDAPB disclosed in Advanced Material, 6, p. 677 (1994).

The thickness of the HIL may be in a range of 2 nm to 100 nm, for example, the thickness may be 50 nm. When the thickness of the HIL is less than 2 nm, the HIL may be too thin and an insufficient amount of holes may be injected. On the other hand, when the thickness of the HIL is greater than 100 nm, light transmission may be reduced, and the resistance of the HIL may be increased.

A material for forming an HTL may be deposited on the HIL, using a vacuum deposition process, a spin coating process, a casting process, or a Langmuir Blodgett (LB) deposition process. The vacuum deposition process may be desirable, because a homogeneous film can be easily obtained, which has very few pinholes. When the HTL is formed using the vacuum deposition process, the deposition conditions may be altered, according to the particular HTL forming material, and can be similar to conventional deposition conditions that are used to form an HIL.

The HTL forming material is not particularly limited and can be N,N′-bis(3-methylphenyl)-N,N′-diphenyl-[1,1-biphenyl]-4,4′-diamine(TPD), or N,N′-di(naphthalene-1-yl)-N,N′-diphenyl benzidine(α-NPD), for example. Then, an EML is formed on the HTL. A material for forming the EML is not particularly limited. The EML may be formed using a vacuum deposition process, a spin coating process, a casting process, or a LB deposition process.

The EML forming material may be selected from: blue emission materials, such as oxadiazole dimer dyes (Bis-DAPOXP), spiro compounds (Spiro-DPVBi, Spiro-6P), triarylamine compounds, bis(styryl)amine (DPVBi, DSA), 4,4′-bis(9-ethyl-3-carbazobinylene)-1,1′-biphenyl (BCzVBi), perylene, 2,5,8,11-tetra-tert-butylperilene (TPBe), 9H-carbazole-3,3′-(1,4-phenylene-di-2,1-ethene-diyl)bis[9-ethyl-(9C)] (BCzVB), 4,4-bis[4-(di-p-tolylamino)styryl]biphenyl (DPAVBi), 4-(di-p-tolylamino)-4′-[(di-p-tolylamino)styryl]stylbene (DPAVB), 4,4′-bis[4-(diphenylamino)styryl]biphenyl (BDAVBi), or bis(3,5-difluoro-2-(2-pyridyl)phenyl-(2-carboxypyridyl)iridium III (FIrPic); green emission materials, such as 3-(2-benzothiazolyl)-7-(diethylamino)coumarine (Coumarin 6), 2,3,6,7-tetrahydro-1,1,7,7,-tetramethyl-1H,5H, 11H-10-(2-benzothiazolyl)quinolizino-[9,9a,1gh]coumarine (C545T), N,N′-dimethyl-quinacridone (DMQA), or tris(2-phenylpyridine)iridium (III) (Ir(ppy)₃); and red emission materials, such as tetraphenylnaphthacene rubrene, tris(1-phenylisoquinoline)iridium(III) (Ir(piq)₃), bis(2-benzo[b]thiophene-2-yl-pyridine)(acetalacetonate)iridium(III) (Ir(btp)₂(acac)), tris(dibenzoylmethane)phenanthroline europium(III) (Eu(dbm)₃(phen)), tris[4,4′-di-tert-butyl-(2,2′)-bipyridine]rutenium(III)complex(Ru(dtb-bpy)₃*2(PF₆)), DCM1, DCM2, Eu (thenoyltrifluoroacetone)₃(Eu(TTA)₃, or (butyl-6-(1,1,7,7-tetramethyljulolidyl-9-enyl)-4H-pyran (DCJTB). The EML forming material may be a polymer selected from the group consisting of a phenylene-based polymer, a phenylene vinylene-based polymer, a thiophene-based polymer, a fluorene-based polymer, and a spiro-fluorene based polymer, for example.

The thickness of the EML may be in a range of 10 nm to 500 nm, for example 50 nm to 120 nm. In particular, the thickness of a blue EML may be 70 nm. When the thickness of the EML is less than 10 nm, a leakage current may be increased, and the luminescent efficiency and lifetime of the organic luminescence device may be decreased. On the other hand, when the thickness of the EML is greater than 500 nm, an operating voltage of the organic luminescence device may be increased.

In some cases, the EML may be formed by using a mixture of the EML forming materials, such as an EML dopant and an EML host. EML hosts can be categorized into fluorescent luminescence EML hosts and phosphorescent luminescence EML hosts. Examples of fluorescent luminescence EML hosts include tris(8-hydroxy-quinolinato)aluminum (Alq3), 9,10-di(naphthy-2-yl)anthracene (AND), 3-Tert-butyl-9,10-di(naphthy-2-yl)anthracene (TBADN), 4,4′-bis(2,2-diphenyl-ethene-1-yl)-4,4′-dimethylphenyl (DPVBi), 4,4′-bisBis(2,2-diphenyl-ethene-1-yl)-4,4′-dimethylphenyl (p-DMDPVBi), Tert(9,9-diarylfluorene)s (TDAF), 2-(9,9′-spirobifluorene-2-yl)-9,9′-spirobifluorene (BSDF), 2,7-bis(9,9′-spirobifluorene-2-yl)-9,9′-spirobifluorene (TSDF), bis(9,9-diarylfluorene)s (BDAF), and 4,4′-bis(2,2-diphenyl-ethene-1-yl)-4,4′-di-(tert-butyl)phenyl (p-TDPVBi). Examples of phosphorescent luminescence EML hosts include 1,3-bis(carbazole-9-yl)benzene (mCP), 1,3,5-tris(carbazole-9-yl)benzene (tCP), 4,4′,4″-tris(carbazole-9-yl)triphenylamine (TcTa), 4,4′-bis(carbazole-9-yl)biphenyl (CBP), 4,4′-bisBis(9-carbazolyl)-2,2′-dimethyl-biphenyl (CBDP), 4,4′-bis(carbazole-9-yl)-9,9-dimethyl-fluorene (DMFL-CBP), 4,4′-bis(carbazole-9-yl)-9,9-bisbis(9-phenyl-9H-carbazole)fluorene (FL-4CBP), 4,4′-bis(carbazole-9-yl)-9,9-di-tolyl-fluorene (DPFL-CBP), and 9,9-bis(9-phenyl-9H-carbazole)fluorene (FL-2CBP).

The amount of the EML dopant may differ, according to the EML forming material, and may be in a range of 3 to 20 parts by weight, based on 100 parts by weight of the EML forming material (the total amount of the EML host and the EML dopant). When the amount of the EML dopant is outside the range described above, the luminescent efficiency of the organic luminescence device may be degraded. According to an exemplary embodiment of the present invention, the EML dopant can be 4,4′-bis[4-(di-p-tolylamino)styryl]biphenyl(DPAVBi), and the EML host can be ADN (9,10-di(naph-2-thyl)anthracene) or TBADN (3-tert-butyl-9,10-di(napht-2-thyl)anthracene):

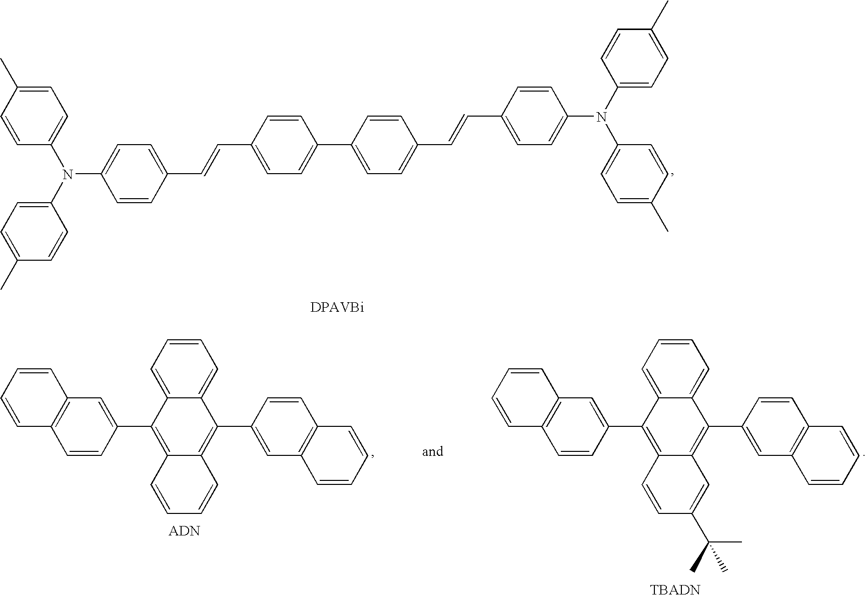

Then, an electron transporting material and the metal oxide represented by Formula 1 are deposited on the EML, using a vacuum deposition process, to form an ETL. The amount of the metal oxide represented by Formula 1 may be in the range of 50 to 150 parts by weight, based on 100 parts by weight of the electron transporting material. When the amount of the metal oxide represented by Formula 1 is less than 50 parts by weight, an injection barrier may be elevated with respect to the cathode. On the other hand, when the amount of the metal oxide represented by Formula 1 is greater than 150 parts by weight, electron flow characteristics may be degraded and a driving voltage may be increased.

The electron transporting material may have an electron mobility of at least 10⁻⁸ cm/V, specifically 10⁻³ to 10⁻⁵ cm/V, in an electric field of 800-1000 (V/cm)^{1/2}. When the electron mobility of the ETL is less than 10⁻³ cm/V, electrons are insufficiently injected to the EML, which is undesirable in terms of charge balance.

The electron transporting material may be bis(10-hydroxcebenzo[h]quinolinatoberilium(BeBq2) represented by Formula 2, a derivative thereof, or Znq2.

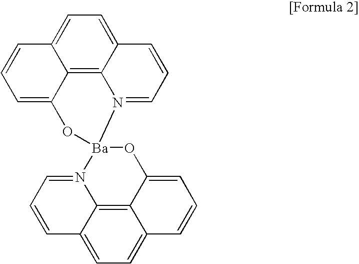

According to aspects of the present invention, electron injection characteristics are enhanced, without the formation of an EIL. However, when an EIL, which facilitates the injection of electrons from a cathode, is formed on the ETL, electron injection characteristics can be enhanced.

An EIL can be formed by depositing LiF, NaCl, CsF, Li₂O, or BaO, on the ETL. The deposition conditions for the ETL and the EIL may differ, according to the ETL forming material and the EIL forming material. The deposition conditions may be similar to conventional deposition conditions that are used to form an HIL.

Finally, a metal can be deposited on the EIL or ETL, using a vacuum deposition process or a sputtering process, to form a second electrode. The second electrode may be a cathode. The second electrode has a low work function and may be formed of a metal, an alloy, an electro-conductive compound, or a mixture thereof. For example, the second electrode may be formed of Li, Mg, Al, Al—Li, Ca, Mg—In, or Mg—Ag. If the organic luminescence device is a front-emission type luminescence display device, the second electrode may be formed of ITO, or IZO, to obtain suitable transmission properties.

A method of manufacturing an organic luminescence device, according to another exemplary embodiment of the present invention, will now be described in detail, with reference to the organic luminescence device of FIG. 2. The method is similar to the previously described method, except that an ETL in the current embodiment has a double-layered structure. In other words, a first electron transporting material is deposited on the EML, using a vacuum deposition process to form a first ETL. Then a second electron transporting material and the metal oxide represented by Formula 1 are deposited on the first ETL, using a vacuum deposition process, to form a second ETL.

The aspects of the present invention will be described in further detail, with reference to the following examples. These examples are for illustrative purposes only and are not intended to limit the scope of the present invention.

### Example 1

### Manufacture of Organic Luminescence Device

To form an anode, a Corning 15 Ω/cm² (1200 Å) ITO glass substrate was cut to a size of 50 mm×50 mm×0.7 mm, then sonicated in isopropyl alcohol and distilled water for 5 minutes apiece, and then washed with ultraviolet (UV) ozone for 30 minutes. Then m-TDATA was then deposited on the anode, to form an HIL having a thickness of 60 nm.

NPB was vacuum deposited on the HIL, to form an HTL having a thickness of 40 nm. Then 100 parts by weight of Alq3 (an EML host) and 3 parts by weight of C545T (an EML dopant) were vacuum deposited on the HTL, to form an EML having a thickness of 70 nm. Then 100 parts by weight of BeBq2 and 100 parts by weight of Li₂O (an electron transporting material) were vacuum co-deposited on the EML, to form an ETL having a thickness of 35 nm. Finally, Al was deposited on the ETL to form a cathode having a thickness of 3000 Å, thereby completing the manufacture of an organic luminescence device.

### Example 2

### Manufacture of Organic Luminescence Device

To form an anode, a Corning 15 Ω/cm² (1200 Å) ITO glass substrate was cut to a size of 50 mm×50 mm×0.7 mm, then sonicated in isopropyl alcohol and distilled water for 5 minutes apiece, and then washed with ultraviolet (UV) ozone for 30 minutes. Then m-TDATA was then deposited on the anode, to form an HIL having a thickness of 60 nm.

NPB was vacuum deposited on the HIL, to form an HTL having a thickness of 40 nm. Then 100 parts by weight of Alq3 (an EML host) and 3 parts by weight of C545T (an EML dopant) were vacuum deposited on the HTL, to form an EML having a thickness of 70 nm. BeBq2 was then vacuum deposited on the EML to form an ETL1 having a thickness of 20 nm.

Then 100 parts by weight of BeBq2 and 100 parts by weight of BaO were vacuum co-deposited on the ETL1, to form an ETL2 having a thickness of 15 nm. Finally, Al was deposited on the ETL2 to form a cathode having a thickness of 3000 Å, thereby completing the manufacture of an organic luminescence device.

### Comparative Example 1

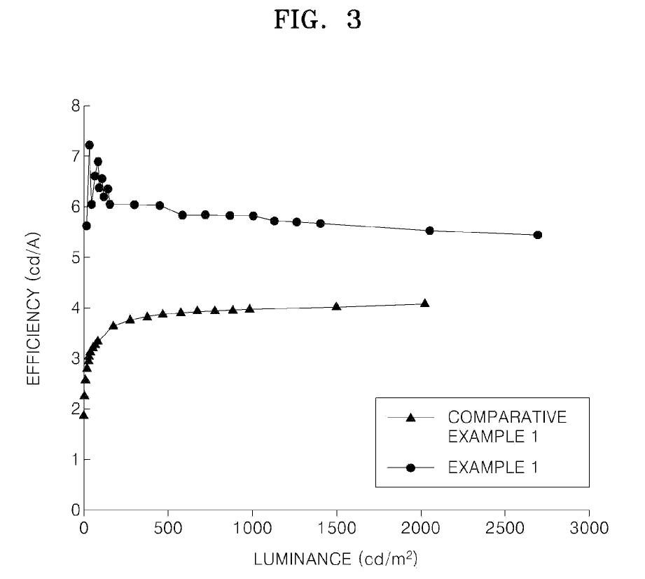

An organic luminescence device was manufactured in the same manner as in Example 1, except an ETL was formed by depositing only BeBq2. Power efficiency with respect to luminance, of the organic luminescence devices prepared according to Example 1 and Comparative Example 1, was measured. The results are shown in the graph of FIG. 3. Referring to FIG. 3, it can be seen that the organic luminescence device prepared according to Example 1 had better power efficiency than the organic luminescence device prepared according to Comparative Example 1.

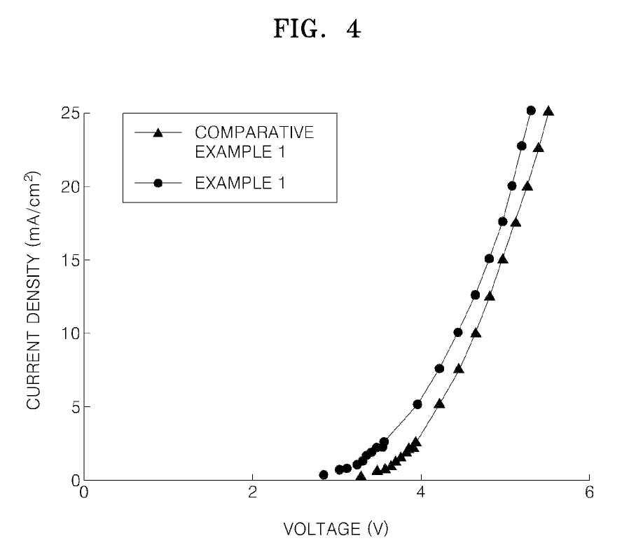

Current density with respect to voltage, of the organic luminescence devices prepared according to Example 1 and Comparative Example 1, was measured. The results are shown in the graph of FIG. 4. Referring to FIG. 4, it can be seen that the organic luminescence device prepared according to Example 1 had a higher current density than the organic luminescence device prepared according to Comparative Example 1.

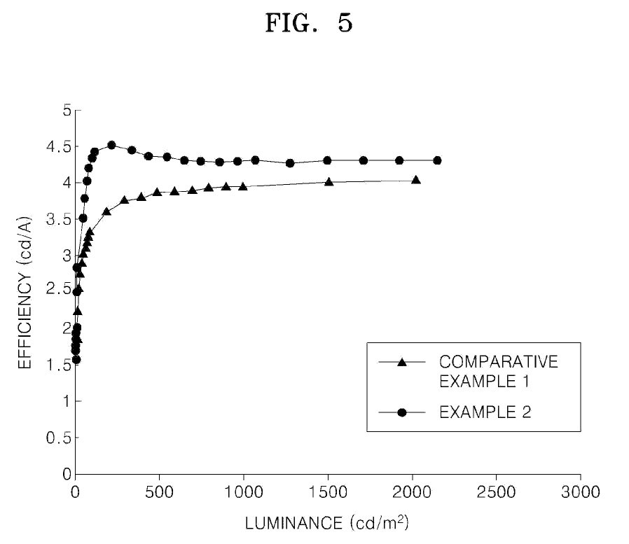

Current efficiency with respect to luminance, of the organic luminescence devices prepared according to Example 2 and Comparative Example 1, was measured. The results are shown in the graph of FIG. 5. Referring to FIG. 5, it can be seen that the organic luminescence device prepared according to Example 2 had a higher current efficiency than the organic luminescence device prepared according to Comparative Example 1.

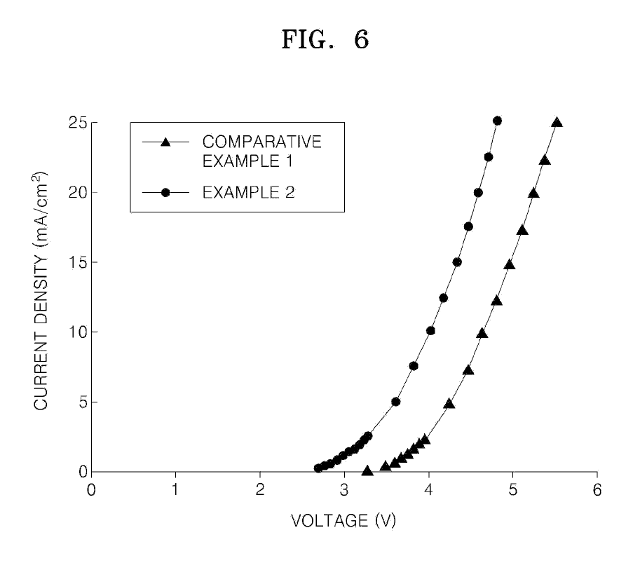

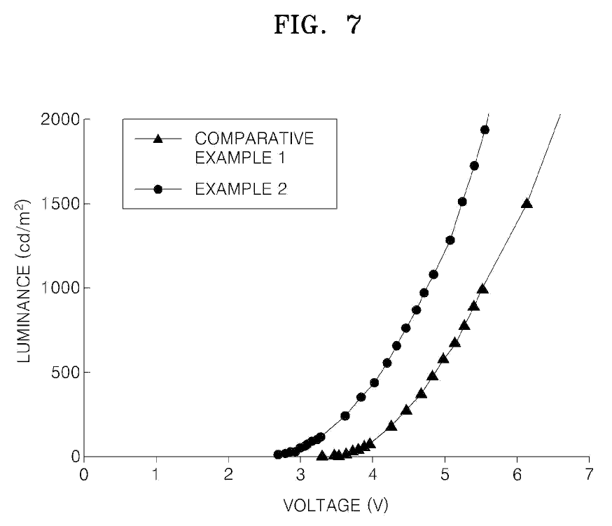

Current density with respect to voltage, of the organic luminescence devices prepared according to Example 2 and Comparative Example 1, was measured. The results are shown in the graph of FIG. 6. Luminance with respect to voltage, of the organic luminescence devices prepared according to Example 2 and Comparative Example 1, was measured. The results are shown in the graph of FIG. 7.

Referring to FIGS. 6 and 7, it can be seen that the organic luminescence device prepared according to Example 2 had a higher current density and a higher luminance than the organic luminescence device prepared according to Comparative Example 1.

As described above, an organic luminescence device, according to aspects of the present invention, includes a novel electron transporting material to lower an electron injection barrier and to decrease the resistance of an interface between an EML and an ETL. This accordingly reduces the degradation of the organic luminescence device. Therefore, the organic luminescence device has a longer lifetime, a higher current efficiency, and a higher power efficiency than a conventional device that includes a conventional electron transporting material. Furthermore, the numbers of holes and electrons injected to the EML are balanced, and driving characteristics of the organic luminescence device are improved.

Although a few exemplary embodiments of the present invention have been shown and described, it would be appreciated by those skilled in the art that changes may be made in these exemplary embodiments, without departing from the principles and spirit of the invention, the scope of which is defined in the claims and their equivalents.

What is claimed is:

1. An organic luminescence device comprising an electron transport layer, the electron transport layer comprising:
an electron transporting material; and
a metal oxide represented by Formula 1:
AₐO_{b}, [Formula 1]
wherein A is Li, Mo, Ba, B, or Cs, a is a number in the range of 1 to 3, and b is a number in the range of 1 to 3.

2. The organic luminescence device of claim 1, wherein the metal oxide represented by Formula 1 comprises lithium oxide (Li₂O), molybdeum oxide (Mo₁O₃), barium oxide (BaO), or boron oxide (B₂O₃).

3. The organic luminescence device of claim 1, wherein the amount of the metal oxide represented by Formula 1 is in a range of 50 to 150 parts by weight, based on 100 parts by weight of the electron transporting material.

4. The organic luminescence device of claim 1, wherein the electron mobility of the electron transporting material is at least 10⁻⁸ cm/V, in an electric field of from 800 to 1000 (V/cm)^{1/2}.

5. The organic luminescence device of claim 1, wherein the electron transporting material comprises at least one compound selected from the group consisting of bis(8-oxyquinolino)zinc II (Znq2) or bis(10-hydroxybenzo[h]quinolinatoberilium (BeBq2) represented by Formula 2 below:

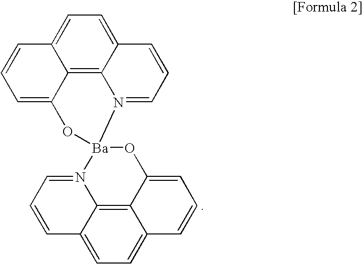

6. The organic luminescence device of claim 1, further comprising:
a first electrode;
a hole transport layer disposed on the first electrode;
an emission layer disposed between the hole transport layer and the electron transport layer; and
a second electrode disposed on the electron transport layer.

7. The organic luminescence device of claim 6, further comprising a hole injection layer disposed between the first electrode and the hole transport layer.

8. An organic luminescence device comprising:
a first electron transport layer comprising a first electron transporting material; and
a second electron transport layer disposed on the first electron transport layer, comprising a second electron transporting material and a metal oxide represented by Formula 1 illustrated below:
AₐO_{b}, [Formula 1]
wherein A is Li, Mo, Ba, B, or Cs, a is a number in the range of 1 to 3, and b is a number in the range of 1 to 3.

9. The organic luminescence device of claim 8, wherein the electron mobility of the first electron transporting material is at least 10⁻⁸ cm/V, in an electric field of 800 to 1000 (V/cm)^{1/2}.

10. The organic luminescence device of claim 9, wherein the electron mobility of the first electron transporting material is in a range of 10⁻⁴ to 10⁻⁸ cm/vs, in an electric field of 800 to 1000 (V/cm)^{1/2}.

11. The organic luminescence device of claim 8, wherein the ratio of the thickness of the first electron transport layer to the thickness of the second electron transport layer is in a range of 1:1 to 2:1.

12. The organic luminescence device of claim 9, wherein, in the second electron transport layer, the amount of the metal oxide represented by Formula 1 is in a range of 50 to 150 parts by weight, based on 100 parts by weight of the second electron transporting material.

13. The organic luminescence device of claim 8, wherein the metal oxide represented by Formula 1 comprises lithium oxide (Li₂O), molybdeum oxide (Mo₁O₃), barium oxide (BaO), or boron oxide (B₂O₃).

14. The organic luminescence device of claim 8, further comprising:
a first electrode;
a hole transport layer disposed on the first electrode;
an emission layer disposed on the hole transport layer; and
a second electrode disposed on the second electron transport layer.

15. The organic luminescence device of claim 14, further comprising a hole injection layer disposed between the first electrode and the hole transport layer.

16. The organic luminescence device of claim 8, wherein the first and second electron transporting materials are independently selected from the group consisting of ZnQ2 and BeBq2.

17. An organic luminescence device comprising an electron transport layer, the electron transport layer comprising:
a first electrode;
a hole transport layer disposed on the first electrode;
an emission layer disposed on the hole transport layer;
a first electron transport layer disposed on the emission layer, comprising,
an electron transporting material, and
a metal oxide selected from the group consisting of lithium oxide (Li₂O), molybdeum oxide (Mo₁O₃), barium oxide (BaO), or boron oxide (B₂O₃); and
a second electrode disposed on the first electron transport layer.

18. The organic luminescence device of claim 17, further comprising a hole injection layer disposed between the first electrode and the hole transport layer.

19. The organic luminescence device of claim 17, further comprising a second electron transport layer disposed between the first electron transport layer and the emission layer, comprising the electron transporting material.

20. The organic luminescence device of claim 17, wherein in the first electron transport layer, the amount of the metal oxide represented by Formula 1 is in a range of 50 to 150 parts by weight, based on 100 parts by weight of the second electron transporting material.

21. The organic luminescence device of claim 17, wherein the ratio of the thickness of the second electron transport layer to the thickness of the first electron transport layer is in a range of 1:1 to 2:1.
